(19) United States
(12) Patent Application Publication
(10) Pub. No.: US 2018/0331245 A1
(43) Pub. Date: Nov. 15, 2018

(54) Dual-junction thin film solar cell module, and preparation method thereof

(71) Applicant: BEIJING CHUANGYU TECHNOLOGY CO., LTD., Beijing (CN)

(72) Inventors: Shihai GU, Beijing (CN); Qingzhao ZHANG, Beijing (CN)

(21) Appl. No.: 15/775,012

(22) PCT Filed: Nov. 1, 2016
(86) PCT No.: PCT/CN2016/104203

§ 371 Date: May 10, 2018

(30) Foreign Application Priority Data
Nov. 20, 2015 (CN) 201510809748.0

(51) Int. Cl. H01L 31/0725; H01L 31/0216; H01L 31/0224; H01L 31/18; H01L 31/0336; H01L 31/0465

(52) U.S. Cl. CPC H01L 31/0725; H01L 31/02168; H01L 31/022433; H01L 31/0465; H01L 31/18; H01L 31/0336; H01L 31/022441

(57) ABSTRACT

Provided are a dual-junction thin film solar cell module, and preparation method thereof. The cell module is formed by multiple cell units connected in series, and each cell unit comprises a selectively grown substrate (105), a bottom cell (106), and a top cell (126). A front metal electrode layer (200) is provided on the top cell (126), and the selectively grown substrate (105) comprises a metal base (100), a patterned insulation layer (102), and an N-type microcrystalline germanium seed layer (104), the insulation layer (102) is formed on the metal base (100), and the N-type microcrystalline germanium seed layer (104) is in the pattern formed by the insulation layer (102). The bottom cell (106) is a polycrystalline germanium bottom cell layer, and the top cell (126) is a GaAs cell. An N-type diffusion layer (108), an N-type buffer layer (110), an N-type region (112) of a tunnel junction, and a P-type region (114) of the tunnel junction are sequentially grown from the polycrystalline germanium bottom cell (106) to the top cell (126). An antireflection layer (300) is formed on the front metal electrode layer (200).

### RELATED APPLICATION

The present application for invention claims a right of priority of the Chinese application for a patent entitled “Dual-junction thin film solar cell module, and preparation method thereof”, with the application number 201510809748.0 filed on Nov. 20, 2015, and it is referred to in full text here as a reference.

### TECHNICAL FIELD

The present invention relates to the preparation method of III-V family dual-junction thin film cell module, and in particular to a dual-junction thin film solar cell module comprising a selectively grown substrate and a preparation method thereof.

### BACKGROUND

In 1954 it was firstly found in the world that GaAs material had a photovoltaic effect. In the 1960s, the Gobat team developed the first zinc-doped GaAs solar cell, merely having a conversion rate from 9% to 10%, far lower than the theoretic value 27%. The earliest monocrystalline GaAs cell has basically the same preparation method as the current monocrystalline silicon, but as a direct band gap semiconductor, it needs an absorption layer of merely several micrometers, and undoubtedly it is a great waste of crystal GaAs.

In the 1970s, the research institutes represented by IBM and Ioffe Physical-Technical Institute of the former Soviet Union introduced a heterogeneous GaAIAs window layer using the LPE (liquid phase epitaxy) technology, reducing the recombination rate of the GaAs surface and making the efficiency of the GaAs solar cell reach 16%. Soon afterwards, the HRL (Hughes Research Lab) and Spectrolab of the U.S.A enabled the average efficiency of cell to reach 18% by improving the LPE technology, and volume production was realized to create a new era of high-efficiency gallium arsenide solar cell.

After 1980s, the GaAs solar cell technology went through the stages from LPE to MOCVD, from homogenous epitaxy to heterogeneous epitaxy, from uni-junction to multi-junction overlapped structure, and from a LM structure to an IMM structure, presenting an increasingly rapid development speed and a constantly improving efficiency. At present the maximum efficiency has reached 28.8% (alta devices) for a single-junction solar cell, 44.4% (Sharp IMM) for a three-junction, and nearly 50% (Fhg-ISE) for a four-junction lab.

At present the three-junction GaAs cell with a germanium substrate is the focus of research, and there are few researches in dual-junction GaAs cell; a dual-junction cells usually all use GaAs and InGaP as the bottom cell and the top cell, and they are connected by a tunnel junction with low electric and optical losses. For the dual junctions, the problem of matching of band gaps of the bottom cell and the top cell must be considered. Regarding AM0, the best band gap is 1.23 eV and 1.97 eV, and the theoretic efficiency can reach 35.8%. Now it is technically available that lattice matching materials are used to relax the requirement of the band gap Eg. In addition, since the band gap of the bottom cell is 1.42 eV and that of the top cell is about 1.9 eV, a difference between them is merely about 0.48 eV; the band gap of the bottom cell is too large, cannot absorb lights with a wavelength of more than 900 nm, as a result, the photocurrent density of the bottom cell is less than the current density of the top cell, consequently the photocurrent of them does not match, severely lowering the internal quantum efficiency of the cells.

Dual-junction cells which usually take GaAs as the substrate and GaAs and InGaP as the bottom cell and top cell respectively are dual-junction GaAs cells. The cost of this kind of dual-junction cell is higher than that of uni-junction GaAs cell, and the cost of epitaxy is almost two times of the cost of uni-junction, but its efficiency is slightly higher than that of uni-junction, at present the maximum efficiency of uni-junction is 28.8%, and the maximum efficiency of dual-junction is 30.8%, while entailing a large amount of indium as raw material.

In addition, the absorption layers of the dual junctions GaAs and InGaP both have a large thickness; as a result, the entire thickness of the cell is greater than 10 μm. However, a flexible thin film cell is usually required to have a thickness of 1-10 μm, thus this kind of dual-junction cell disable flexibility.

### SUMMARY

In order to achieve flexibility of dual-junction III-V family cells, reduce the preparation costs of dual-junction cells, and improve the electricity-generation efficiency of cells, the present invention provides a dual-junction thin film solar cell module with a selectively grown substrate, and a preparation method thereof.

The technical solution adopted is as follows:

On the one hand, the present invention provides a dual-junction thin film solar cell module formed by multiple cell units connected in series, and each cell unit comprises a selectively grown substrate, a bottom cell, and a top cell. A front metal electrode layer is provided on the top cell, and the selectively grown substrate comprises a metal base, a patterned insulation layer, and an N-type microcrystalline germanium seed layer, the insulation layer is formed on the metal base, and the N-type microcrystalline germanium seed layer is in a pattern formed by the insulation layer. The bottom cell is a polycrystalline germanium bottom cell layer, and the top cell is a GaAs cell. An N-type diffusion layer, an N-type buffer layer, an N-type region of a tunnel junction, and a P-type region of the tunnel junction are sequentially grown from the polycrystalline germanium bottom cell to the top cell. An antireflection layer is formed on the front metal electrode layer.

The buffer layer is an N-type InGaAs—GaAs gradient buffer layer, wherein the proportion of indium changes gradually from 1% to 0%.

The antireflection layer is an MgF₂ or ZnS antireflection layer.

The GaAs cell comprises a P-type AlGaAs back surface field, a P-type GaAs base region, an N-type AlGaAs emitting electrode, an N-type AlGaAs window layer, and an N⁺-type GaAs front-side contact layer that grow epitaxially in order on the P-type region of the tunnel junction, the front metal electrode layer is provided on the front-side contact layer.

The window layer is exposed outside in the front-side contact layer, and its surface forms a rough structure.

On the other hand, the present invention further provides a preparation method of a dual-junction thin film solar cell module, the method comprising:

Step 1: an insulation layer is deposited on a metal base, and the insulation layer is patterned;

Step 2: a microcrystalline germanium seed layer is deposited on a surface of the patterned insulation layer, and redundant microcrystalline germanium materials on the surface of the insulation layer are removed to prepare a selectively grown substrate with a microcrystalline germanium seed layer;

Step 3: a polycrystalline germanium bottom cell layer is deposited on a surface of the selectively grown substrate with the microcrystalline germanium seed layer to prepare a polycrystalline germanium bottom cell;

Step 4: a diffusion layer, a buffer layer, a tunnel junction and a top cell structure are formed sequentially on a surface of the polycrystalline germanium bottom cell layer through epitaxial growth to prepare a dual-junction cell structure;

Step 5: a patterned front metal electrode layer is formed on a top cell structure;

Step 6: the dual-junction cell structure that grows epitaxially above the polycrystalline germanium bottom cell layer is separated into multiple independent cell units;

Step 7: an antireflection layer is formed on the front metal electrode layer, and the antireflection layer, the polycrystalline germanium bottom cell layer, and the selectively grown substrate are cut sequentially to thoroughly separate the cell units;

Step 8: the cell units are connected in series and provides them between an upper flexible substrate and a lower flexible substrate for encapsulation to prepare a thin film cell module.

For “an insulation layer is deposited on a metal base, and the insulation layer is patterned” in step 1, the specific method is as follows: an insulation layer with a thickness of 1-5 μm is deposited on a surface of the metal base; a pattern on the surface of the insulation layer is formed by coating, development and exposure; and redundant materials of the insulation layer are removed by a wet etching to pattern the insulation layer.

In step 2, a highly-doped P-type microcrystalline germanium seed layer is deposited on the surface of the patterned insulation layer using a PECVD device, pure germane and diborane are introduced and heated to 400˜700° C., and grown under a reaction pressure 10⁻²˜10 Pa and a doping concentration 1-3×10¹⁹ cm⁻³ to form the P-type microcrystalline germanium seed layer; the redundant microcrystalline germanium seed layer on the surface of the insulation layer is removed by a chemical etching polishing process to prepare the selectively grown substrate with a microcrystalline germanium seed layer.

For “a diffusion layer, a buffer layer, a tunnel junction and top cell structure are formed sequentially on a surface of the polycrystalline germanium bottom cell layer through epitaxial growth” in the step 4, the specific method is as follows: an N-type InGaP diffusion layer are grown on the surface of the polycrystalline germanium bottom cell layer; element P diffuses into of the polycrystalline germanium bottom cell layer under a high temperature to form a shallow diffusing PN junction; the diffusing layer InGaP is annealed at an atmosphere of PH₃; the buffer layer, the tunnel junction, a back surface field of top cell, a base region, an emitting electrode, a window layer, and a front-side contact layer are grown sequentially on the condition of a constant temperature.

In step 5, a patterned front metal electrode layer is formed on the front-side contact layer of the dual-junction cell structure by a electroplating and a wet etching; and then the front-side contact layer not covered by the front metal electrode layer is removed to expose the window layer and form a rough structure on a surface of the window layer.

In step 8, the separated cell units are connected in series through copper foil, providing them between an upper PET thin film and a lower PET thin film, and them are encapsulated using a laminator to form a flexible thin film cell module.

As compared with the prior art, the present invention has the following advantageous effects:

A. GaAs substrate, polycrystalline germanium and GaAs are used in the present invention as a bottom cell and a top cell respectively of a dual-junction cell. Firstly, a band gap of the polycrystalline germanium bottom cell is 0.65 eV and that of the top cell GaAs is 1.4 eV; this combination is beneficial for dividing the solar spectrum to form reasonable current matching, and for further absorbing lights with the wavelength within the range of 900-2000 nm to make the conversion efficiency of the cell reach 32% (AM1.5).

B. In the present invention, the polycrystalline germanium/gallium arsenide thin film cell structure is grown on the metal base by two-step selective growth process, and the efficiency of the cell is improved through a reasonable band gap matching design; cheaper substrates produced in batches and thinner shallow junction polycrystalline Ge as the bottom cell, less indium materials are used, the metal base itself is used as the back metal electrode layer, and manufacturing costs of the flexible dual-junction GaAs cell are reduced through the technologies like preparation the front-side electrode by a electroplating, thereby low cost, high efficiency and flexibility of the dual-junction III-V family cell used polycrystalline germanium as the bottom cell is achieved.

C. when used as a bottom cell, the polycrystalline germanium in the present invention has lower manufacturing costs than GaAs. Owing to the thickness of the diffusion junction, the thickness of the bottom cell may be less than 1 micrometer and does not need growing a complex cell structure, and only through high-temperature diffusion, PN junctions can be formed, the preparation process is simple. In addition, when used as a bottom cell, polycrystalline germanium has a lower price than GaAs. Moreover, only the buffer layer of the cell needs indium that occupies less than 1% of the materials, which can reduce the limitation of the raw material indium, and therefore greatly reduce the manufacturing costs of the cell.

D. The preparation process of the dual-junction thin film solar cell in the present invention is opposite to the preparation process in the prior art: in the prior art, the front-side and the back metal electrode layers are prepared after the cell structure is prepared; while in the present invention, preparing of the metal base and the patterned insulation layer are firstly completed. The patterned insulation layer plays the role of insulation and reflection, while the patterned metal base can be used as a back metal electrode layer, and thus the preparation process of the cell is simplified.

E. The main function of the microcrystalline germanium seed layer in the present invention is to provide a certain number of nucleation centers for the growth of the polycrystalline germanium bottom cell layer, thus forming better microcrystalline germanium materials, i.e., being secondary selective growth: only microcrystalline germanium materials can be obtained from the technology of conventional growth on the surface of the metal base; in order to obtain polycrystalline germanium, the technology of secondary selective growth is required.

### BRIEF DESCRIPTION OF THE DRAWINGS

For a better understanding of the present invention, the present invention is described hereinafter based on the schematic embodiments of the present invention and in combination with the accompanying drawings. In the accompanying drawings:

FIG. 1 is a diagram of an epitaxial structure of the polycrystalline Ge/GaAs dual-junction cell provided in the present invention;

FIG. 2 is a planform of the metal base structure with a patterned insulation layer;

FIG. 3 is a front view of the metal base structure with a patterned insulation layer;

FIG. 4 is a front view of the growth of a microcrystalline germanium seed layer on a surface of the insulation layer;

FIG. 5 is a structure diagram of the selectively grown substrate provided in the present invention;

FIG. 6 is a structural diagram of formation of a polycrystalline germanium bottom cell layer on the selectively grown substrate;

FIG. 7 is a structure diagram of the front metal electrode layer formed on the polycrystalline Ge/GaAs dual-junction cell;

FIG. 8 is a structure diagram of the polycrystalline Ge/GaAs dual-junction cell; and

FIG. 9 is a block diagram of the preparation method of the dual-junction solar cell module provided in the present invention.

In the drawings, 100—metal base; 102—insulation layer; 104—microcrystalline germanium seed layer; 105—selectively grown substrate; 106—polycrystalline germanium bottom cell layer; 108—diffusion layer; 110—buffer layer; 112—N-type region of a tunnel junction; 114—P-type region of a tunnel junction; 116—back surface field; 118—base region; 120—emitting electrode; 122—window layer; 124—front-side contact layer; 125—epitaxial layer; 126—top cell; 127—dual-junction cell structure; 200—front metal electrode layer; 300—antireflection layer.

### DETAILED DESCRIPTION OF THE EMBODIMENTS

The embodiments of the present invention will be described in detail below with reference to the drawings to make the objective, technical solution and advantages of the present invention more clear.

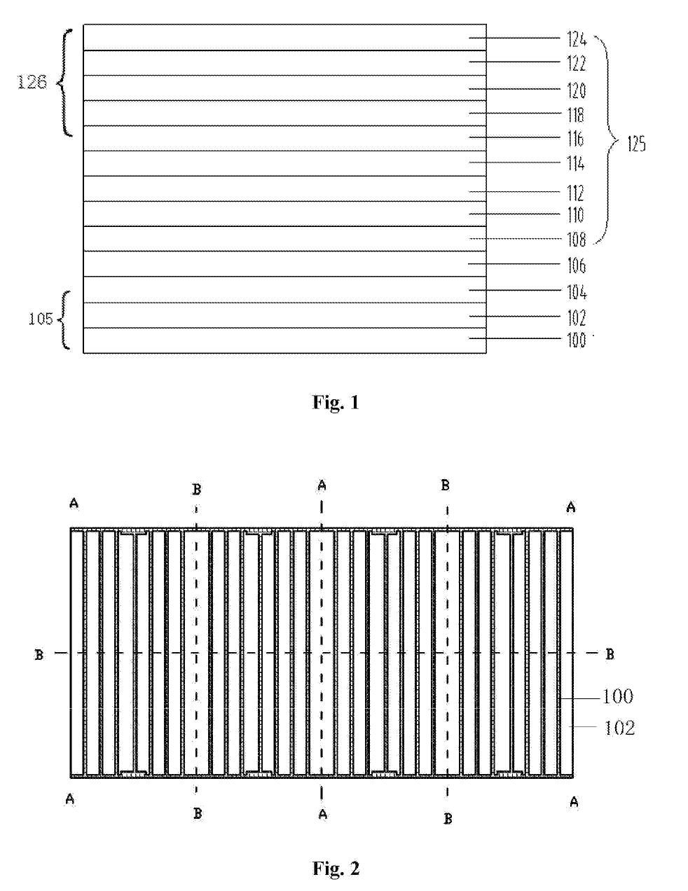

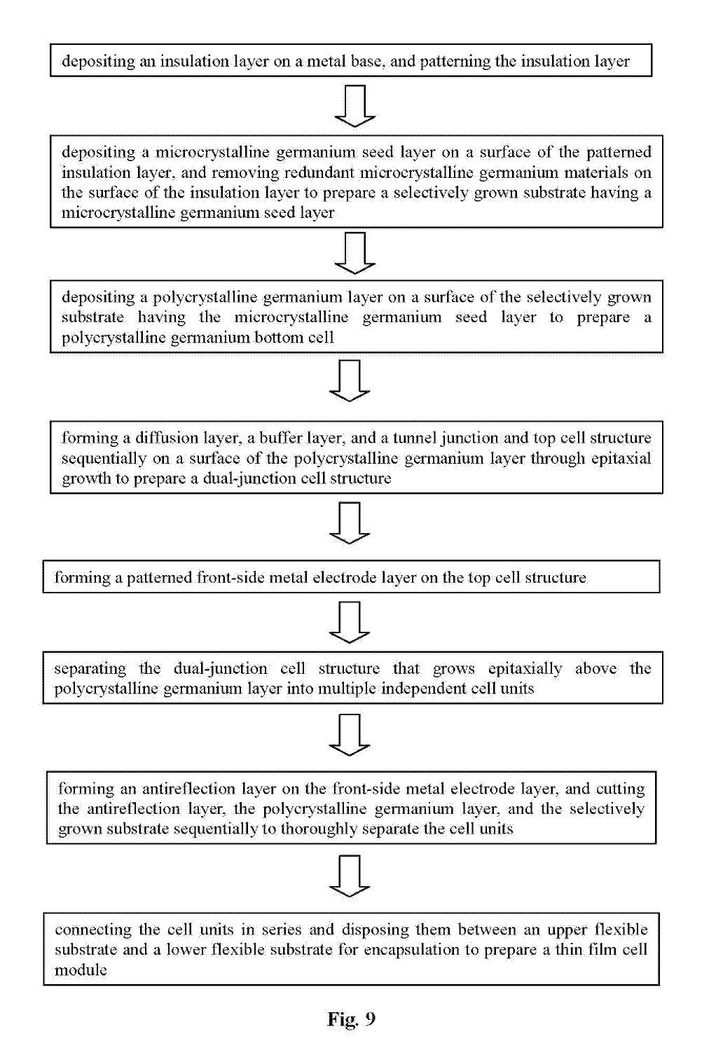

The present invention provides a preparation method of a dual-junction flexible thin film cell which uses polycrystalline Ge (germanium) as bottom cell and GaAs (gallium arsenide) as top cell. In combination with FIGS. 1 and 9, the specific preparation method is as follows:

Step 1: an insulation layer 102 is deposited on a metal base 100, and the insulation layer 102 is patterned.

The metal base 100 with suitable size is produced in batches using a large-size metal base by means of a PECVD (Plasma Enhanced Chemical Vapour Deposition) device. The metal base 100 of this size (both the length and the width are a multiple of the size of the cut substrate) is put to the PECVD device, the metal base 100 can be one of stainless steel foil and Cu foil; the insulation layer 102 with a thickness of 1-5 μm is deposited on a surface of the metal base 100, the insulation layer 102 can be selected from one of the oxygen-nitrogen compound such as SiO₂, Al₂O₃, and SiNₓ.

Secondly, a patterned insulation layer 102 is prepared on the metal base 100 by a photolithography and a wet etching. Patterns are formed on a surface of the insulation layer 102 through a coating, a development and a exposure, and then redundant materials of insulation layer 102 are removed by a wet etching process, and solidified photoresist is removed with acetone to complete preparation of the patterned insulation layer 102 on the metal base 100; moreover, the graphics of the patterned insulation layer 102 is also the graphic structure of the final back metal electrode layer of the cell. Thus, the metal base 100 not only plays the role of a back metal electrode layer, but also plays the role of insulation and reflection owing to the insulation layer 102 deposited thereon.

Step 2: a microcrystalline germanium seed layer 104 is deposited on a surface of the patterned insulation layer 102, and redundant microcrystalline germanium materials on the surface of the insulation layer 102 are removed to prepare a selectively grown substrate 105 with the microcrystalline germanium seed layer 104.

A selectively grown highly-doped P-type microcrystalline germanium seed layer 104 is deposited on a surface of the patterned insulation layer 102 using the PECVD device, and the redundant microcrystalline germanium materials on the surface of the insulation layer 102 are removed by the chemical etching polishing to prepare a selectively grown substrate 105 with the microcrystalline germanium seed layer 104.

As shown in FIG. 2, the selectively grown substrate 105 is separated in direction A by a laser cutting technique to finish the preparation of the selectively grown substrate 105.

The highly-doped microcrystalline germanium seed layer 104 is both the basis for growing a polycrystalline germanium bottom cell layer 106 in the next step and a channel of the cell bottom for transferring carriers.

Step 3: a polycrystalline germanium bottom cell layer 106 is deposited on a surface of the selectively grown substrate 105 with the microcrystalline germanium seed layer 104 to prepare a polycrystalline germanium bottom cell. A low doped P-type polycrystalline germanium bottom cell layer 106 with a thickness of about 5 μm is deposited on a surface of the selectively grown substrate 105 with the microcrystalline germanium seed layer 104 using an LPCVD (Low Pressure Chemical Vapor Deposition) device to prepare a polycrystalline germanium bottom cell, as shown in FIG. 6.

Step 4: a diffusion layer 108, a buffer layer 110, and a tunnel junction and a top cell structure 126 are formed sequentially on a surface of the polycrystalline germanium bottom cell layer 106 through epitaxial growth to prepare a dual-junction cell structure 127.

The dual-junction cell structure 127 is formed on the bottom cell through epitaxial growth using epitaxial devices such as MOCVD (Metal-organic Chemical Vapor Deposition). An epitaxial temperature is 630-670° C. and a pressure is 50-100 torr, wherein the preferred epitaxial temperature is 650° C. and the preferred pressure is 76 torr.

Specifically, a shallow junction bottom cell is firstly formed on the surface of the polycrystalline germanium bottom cell layer 106 through diffusion, wherein the main diffusion element is phosphorus, and annealing treatment is carried out for the diffusing layer 108 to remove interface defects and ensure the crystal quality on the surface of the diffusing layer 108, which is beneficial for further epitaxial growth to form the tunnel junction and the top cell 126.

Then the buffer layer 110, the tunnel junction, a back surface field 116 of the top cell 126, a base region 118, an emitting electrode 120, a window layer 122, and a front-side contact layer 124 are grown sequentially on the diffusion layer 108 on the condition of a constant temperature, and the temperature is lowered to a room temperature after the growth of epitaxial layer is completed, so as to prepare the dual-junction cell structure 127, as shown in FIG. 8.

An annealing treatment is introduced to the above preparation method, can further improve the crystal quality of the tunnel junction and the top cell; the structure of the top cell is made of GaAs and AlGaAs, can reduce the use amount of the raw material of In; moreover, the entire process does not need changing the temperature, and growth of the epitaxial layer is completed on the condition of a constant temperature.

Step 5: a patterned front metal electrode layer 200 is formed on the top cell structure.

The front-side contact layer 124 is plated with a metal layer using a entire-surface electroplating technique to form a front metal electrode layer 200, a part of front metal electrode layer 200 is removed by the wet etching to form a front-side patterned electrode structure; when the metal layer is a copper electrode layer, its etching liquid is a mixed liquid of FeCl₃ and HCl. The front-side contact layer 124 not covered by electrode is removed by a wet etching to reveal the window layer 122 and form a rough structure on a surface of the window layer 122, an etching liquid is a mixture of NH₄OH and H₂O₂, and an etching is at a room temperature.

Step 6: the dual-junction cell structure 127 that grows epitaxially above the polycrystalline germanium bottom cell layer 106 is separated into multiple independent cell units.

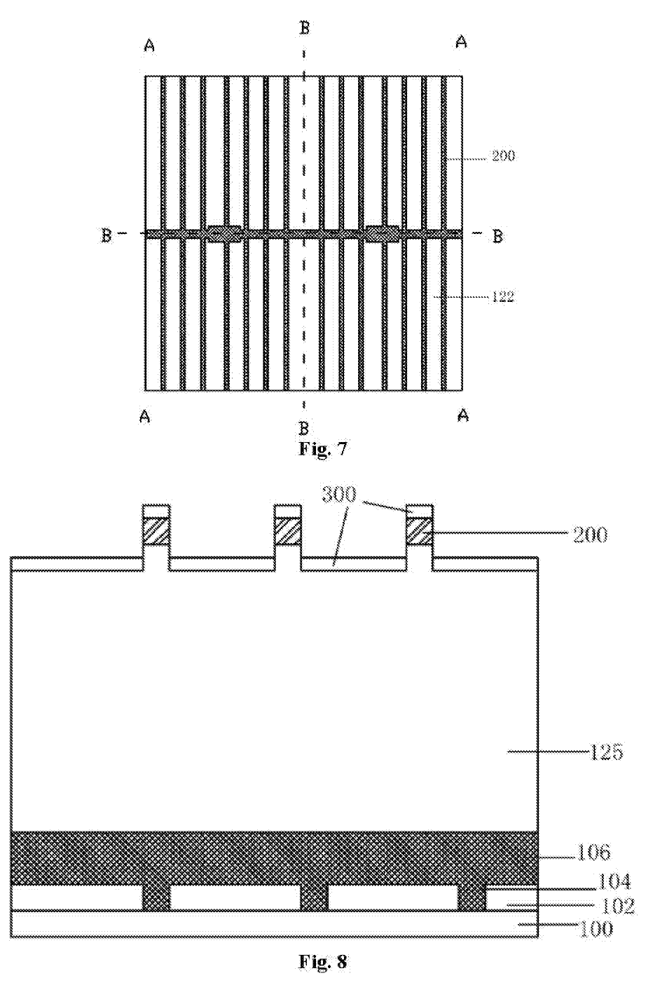

As shown in FIG. 7, the cell is separated preliminarily in direction B by a wet etching, and is etched until the polycrystalline germanium bottom cell layer 106, etching liquids with different proportions of H₃PO₄—H₂O₂ mixture and HCl—C₂H₆O₂ mixture are used sequentially for corrosion.

Step 7: an antireflection layer 300 is formed on the front metal electrode layer 200 using the devices such as PECVD, and the antireflection layer 300, the polycrystalline germanium bottom cell layer 106, and the selectively grown substrate 105 are cut sequentially along the positions of the wet etching by the laser cutting to separate the cell units thoroughly.

Step 8: the cell units are connected in series and they are provided between an upper flexible substrate and a lower flexible substrate for encapsulation to prepare a thin film cell module; adjacent cells are connected in series through copper foil, and they are encapsulated using a laminator.

The dual-junction thin film solar cell module formed using the above preparation method is shown in FIGS. 8 and 1.

The cell module is formed by connecting multiple cell units in series, each of the cell units comprises a selectively grown substrate 105, a bottom cell and a top cell 126, on which there is provided a front metal electrode layer 200, the bottom cell is a polycrystalline germanium bottom cell layer 106, the selectively grown substrate 105 comprises a patterned metal base 100, a patterned insulation layer 102, and an N-type microcrystalline germanium seed layer 104, the insulation layer 102 is formed on the metal base 100, the N-type microcrystalline germanium seed layer 104 is in the pattern formed by the insulation layer 102; the top cell 126 is a gallium arsenide (GaAs) cell, and an N-type diffusion layer 108, an N-type buffer layer 110, an N-type region 112 of a tunnel junction, and a P-type region 114 of the tunnel junction are grown sequentially between the polycrystalline germanium bottom cell layer 106 and the top cell 126, and an antireflection layer 300 is formed on the front metal electrode layer 200. The buffer layer 110 is an N-type InGaAs—GaAs gradient buffer layer, wherein the proportion of indium changes gradually from 1% to 0%. The antireflection layer 300 is an MgF₂ or ZnS antireflection layer.

The GaAs cell comprises a P-type AlGaAs back surface field 116, a P-type GaAs base region 118, an N-type AlGaAs emitting electrode 120, an N-type AlGaAs window layer 122, and an N⁺-type GaAs front-side contact layer 124 that are grown epitaxially in order on the P-type region 114 of the tunnel junction, the front metal electrode layer 200 is provided on the front-side contact layer 124, and the window layer 122 is exposed outside in the front-side contact layer 124, and its surface forms a rough structure.

The preparation method of the dual-junction thin film cell module is described hereinafter in combination with embodiments.

Step 1: the metal base 100 is produced in batches by a wet etching and a PECVD device, the metal base 100 can be a specific shape such as a square, circle or rectangle. Firstly an insulation layer 102 is deposited on a surface of the metal base 100 using the PECVD device, wherein the insulation layer 102 has a function of reflecting lights. The insulation layer 102 can be made of SiO₂, Al₂O₃, SiNₓ, etc. SiO₂ insulation layer is used in the present embodiment. Firstly evacuated to 5 Pa, heated to a temperature of 300° C.; then Ar and TEOS are introduced, Ar: 200 sccm, TEOS: 30 sccm, air pressure: 50 Pa; RF voltage is opened, and the power is adjusted to 300 W; the deposited thin film has a thickness of 5 μm.

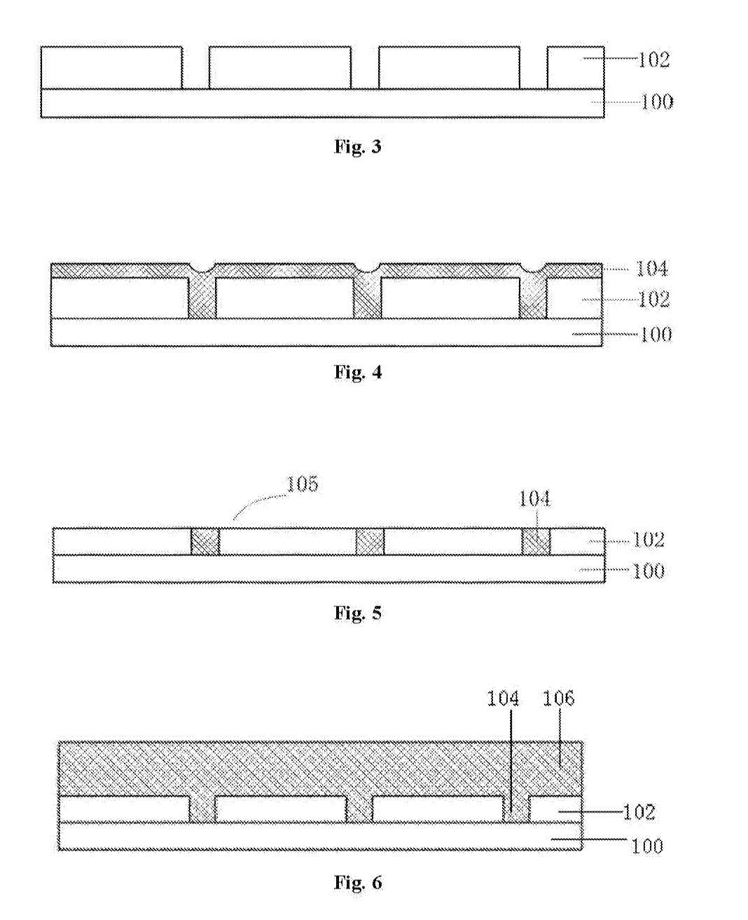

Forming a pattern on the surface of the insulation layer 102 by a photoresist coating, a development and an exposure sequentially, redundant materials of insulation layer 102 are removed by a wet etching, and solidified photoresist is removed by a degumming fluid to form the patterned insulation layer 102, as shown in FIG. 3.

SU-8 positive photoresist is spin coated, with a thickness of about 5 μm, a line width of 1-2 μm, and a line spacing of 5-10 micrometers; rinsed by deionized water; wherein an etching liquid is concentrated sulfuric acid used for etching the insulation layer, etching for 10 minutes at 20˜60° C.; then the solidified positive photoresist is removed by an acetone, cleaned after removing the solidified positive photoresist.

Step 2: as shown in FIG. 4, a microcrystalline germanium seed layer 104 is deposited in the pattern formed by the insulation layer 102 using a PECVD device, heat to 400˜700° C., pure germane and diborane are introduce to the growth chamber, flow ratio of pure germane and diborane is controlled, wherein the pressure in the reaction chamber is 10²˜10 Pa, an N-type microcrystalline germanium seed layer with a thickness of 2 μm is grown, wherein its doping concentration is 1×10¹⁹-3×10¹⁹ cm⁻³.

As shown in FIG. 5, redundant microcrystalline germanium materials on the surface of the insulation layer 102 are removed by the chemical etching polishing process to prepare a selectively grown substrate 105 with the microcrystalline germanium seed layer 104; wherein an etching liquid is a mixed etching solution of hydrogen peroxide and sodium hydroxide.

As shown in FIG. 2, the selectively grown substrate 105 is separated in direction A using a laser cutting technique to finish the preparation of the selectively grown substrate 105.

As shown in FIG. 6, a polycrystalline germanium bottom cell layer 106 is deposited on the surface of the selectively grown substrate using a LPCVD device; the selectively grown substrate 105 is heated to 500˜800° C., pure germane and diborane are introduced to the growth chamber, flow ratio of pure germane and diborane is controlled, wherein the pressure in the growth room is 1˜200 torr, an N-type polycrystalline germanium bottom cell layer 106 with a thickness of 1-5 μm is grown, wherein its doping concentration is 1×10¹⁷ cm⁻³.

Step 3: A dual-junction cell structure 127 is prepared through epitaxial growth on the polycrystalline germanium bottom cell layer 106 using an epitaxial device such as MOCVD, as shown in FIGS. 8 and 1. An epitaxial temperature is 630˜670° C. and a pressure is 50˜100 torr, and in the embodiment the epitaxial temperature 650° C. and the pressure 76 torr are adopted.

(1) The temperature is raised to 650° C., and a 20 nm N-type InₓGa₁₋ₓP diffusion layer 108 is grown on the surface of the polycrystalline germanium bottom cell layer 106, wherein x≈0.5; then raising the temperature to 750° C., keeping it for some time, and then the temperature is dropped to 650° C., anneal at an atmosphere of PH₃, and the crystal quality of the surface of the diffusion layer 108 is improved;

(2) A 80 nm to 200 nm N-type InGaAs gradient buffer layer 110 is grown on the surface of the diffusion layer 108, wherein the proportion of In decreases gradually from 1% to 0%;

(3) A 20 nm N⁺-type GaAs N-type region 112 of the tunnel junction is grown on the surface of the buffer layer 110;

(4) A 20 nm P⁺-type AlₓGa₁₋ₓAs P-type region 114 of the tunnel junction is grown on the surface of the N-type region 112 of the tunnel junction, wherein x≈0.7;

(5) A 40 nm P-type AlₓGa₁₋ₓAs back surface field 116 is grown on the surface of the P-type region 114 of the tunnel junction, wherein x≈0.7;

(6) A 3,000 nm P-type GaAs base region 118 is grown on the surface of the back surface field 116;

(7) A 50 nm N-type AlₓGa₁₋ₓAs emitting electrode 120 is grown on the surface of the base region 118, wherein x≈0.3;

(8) A 20 nm N-type (AlₓGa₁₋ₓ)_{y}In_{1-y}P window layer 122 is grown on the surface of the emitting electrode 120, wherein x≈0.7, y≈0.5; and

(9) A 20 nm N⁺-type GaAs front-side contact layer 124 is grown on the surface of the window layer 122.

Step 5: a patterned front metal electrode layer 200 is formed on the top cell 126 structure, as shown in FIG. 7; The front side of the cell is cleaned, and the front metal electrode layer 200 is deposited on a surface of the front-side contact layer 124 by a electroplating, wherein the thickness of the electrode layer is 1-10 μm, and copper or copper nickel alloy is selected as the material. Unnecessary metal electrode layer 200 is removed by a photolithography and a wet etching to form a patterned front-side electrode pattern, wherein an etching liquid is 30% FeCl₃+4% HCl+H₂O, and the etching is at a room temperature. The front-side contact layer not covered by the electrode is removed by the wet etching process to reveal the window layer 122 and form a rough structure on a surface of the window layer 122, wherein an etching liquid is a mixture of NH₄OH and H₂O₂, and the etching is at a room temperature.

Step 6: The epitaxial structure layer 125 at a specific position is separated preliminarily in direction B by a wet etching, as shown in FIG. 2, and etching until the polycrystalline germanium bottom cell layer 106 to separate the epitaxial layer, wherein etching liquids such as different proportions of H₃PO₄—H₂O₂ mixture and HCl—C₂H₆O₂ mixture are used sequentially for etched.

Step 7: An MgF₂ or ZnS antireflection layer 300 is deposited on the front side of the cell using the PECVD device, and the antireflection layer 300, the polycrystalline germanium bottom cell layer 106 of the bottom cell, and the selectively grown substrate 105 are cut by a laser cutting to separate the cells.

Step 8: The adjacent cells are connected in series through copper foil, the serially connected cells are provided between the upper PET and the lower PET, and encapsulated using a laminator to form a flexible thin film cell module.

The above are only the preferred embodiments of the present invention and not intended to limit the present invention. For those skilled in the art, various modifications and changes can be made to the present invention. Any modification, equivalent substitution and improvement made within the spirit and principle of the present invention are intended to be included within the scope of protection of the present invention.

What is claimed is:

1. A dual-junction thin film solar cell module formed by multiple cell units connected in series, each of the cell units comprising a selectively grown substrate, a bottom cell, and a top cell, and a front metal electrode layer is provided on the top cell, wherein the selectively grown substrate comprising a metal base, a patterned insulation layer, and an N-type microcrystalline germanium seed layer, the insulation layer is formed on the metal base, the N-type microcrystalline germanium seed layer is in a pattern formed by the insulation layer; the bottom cell is a polycrystalline germanium bottom cell layer, the top cell is a GaAs cell, an N-type diffusion layer, an N-type buffer layer, an N-type region of a tunnel junction, and a P-type region of the tunnel junction are sequentially grown between the polycrystalline germanium bottom cell layer and the top cell, and an antireflection layer is formed on the front metal electrode layer.

2. The dual-junction thin film solar cell module as claimed in claim 1, wherein the buffer layer is an N-type InGaAs—GaAs gradient buffer layer, wherein the proportion of indium changes gradually from 1% to 0%.

3. The dual-junction thin film solar cell module as claimed in claim 1, wherein the antireflection layer is a MgF₂ antireflection layer or a ZnS antireflection layer.

4. The dual-junction thin film solar cell module as claimed in claim 1, wherein the GaAs cell comprising a P-type AlGaAs back surface field, a P-type GaAs base region, an N-type AlGaAs emitting electrode, an N-type AlGaAs window layer, and an N⁺-type GaAs front-side contact layer that grow epitaxially in order on the P-type region of the tunnel junction, the front metal electrode layer is provided on the front-side contact layer.

5. The dual-junction thin film solar cell module as claimed in claim 4, wherein the window layer is exposed outside in the front-side contact layer, and its surface forms a rough structure.

6. A preparation method of a dual-junction thin film solar cell module, wherein the method comprising:
Step 1: depositing an insulation layer on a metal base, and patterning the insulation layer;
Step 2: depositing a microcrystalline germanium seed layer on a surface of the patterned insulation layer, and removing redundant microcrystalline germanium materials on the surface of the insulation layer to prepare a selectively grown substrate with the microcrystalline germanium seed layer;
Step 3: depositing a polycrystalline germanium bottom cell layer on a surface of the selectively grown substrate with the microcrystalline germanium seed layer to prepare a polycrystalline germanium bottom cell;
Step 4: forming a diffusion layer, a buffer layer, a tunnel junction and a top cell structure sequentially on a surface of the polycrystalline germanium bottom cell layer through epitaxial growth to prepare a dual-junction cell structure;
Step 5: forming a patterned front metal electrode layer on the top cell structure;
Step 6: separating the dual-junction cell structure that grows epitaxially above the polycrystalline germanium bottom cell layer into multiple independent cell units;
Step 7: forming an antireflection layer on the front metal electrode layer, and cutting the antireflection layer, the polycrystalline germanium bottom cell layer, and the selectively grown substrate sequentially to thoroughly separate the cell units; and
Step 8: connecting the cell units in series and providing them between an upper flexible substrate and a lower flexible substrate for encapsulation to prepare a thin film cell module.

7. The preparation method as claimed in claim 6, wherein for depositing an insulation layer on a metal base, and patterning the insulation layer in the step 1, the specific method is as follows: depositing the insulation layer with a thickness of 1-5 μm on a surface of the metal base; forming a pattern on the surface of the insulation layer by coating, development and exposure; and removing redundant materials of the insulation layer by a wet etching to pattern the insulation layer.

8. The preparation method as claimed in claim 6, wherein in the step 2, depositing a highly-doped P-type microcrystalline germanium seed layer on the surface of the patterned insulation layer using a PECVD device, introducing pure germane and diborane and heating to 400˜700° C., and growing under a reaction pressure 10⁻²˜10 Pa and a doping concentration 1×10 cm⁻³-3×10¹⁹ cm⁻³ to form the P-type microcrystalline germanium seed layer; removing the redundant P-type microcrystalline germanium seed layer on the surface of the insulation layer by a chemical etching polishing process to prepare the selectively grown substrate with the P-type microcrystalline germanium seed layer.

9. The preparation method as claimed in claim 6, wherein for forming a diffusion layer, a buffer layer, a tunnel junction and top cell structure sequentially on a surface of the polycrystalline germanium bottom cell layer through epitaxial growth in the step 4, the specific method is as follows: growing an N-type InGaP diffusion layer on the surface of the polycrystalline germanium bottom cell layer; element P diffusing into the polycrystalline germanium bottom cell layer at a high temperature to form a shallow diffusing PN junction; annealing for the InGaP diffusion layer at an atmosphere of PH₃; growing the buffer layer, the tunnel junction, a back surface field of top cell structure, a base region, an emitting electrode, a window layer, and a front-side contact layer sequentially on the condition of a constant temperature.

10. The preparation method as claimed in claim 6, wherein in the step 5, forming the patterned front metal electrode layer on the front-side contact layer of the dual-junction cell structure by a electroplating and a wet etching; and then removing the front-side contact layer not covered by the front metal electrode layer to expose the window layer and form a rough structure on a surface of the window layer.

11. The preparation method as claimed in claim 6, wherein in the step 8, connecting the separated cell units in series through copper foil, providing them between an upper PET thin film and a lower PET thin films and encapsulating using a laminator to form a flexible thin film cell module.

12. The dual-junction thin film solar cell module as claimed in claim 2, wherein the GaAs cell comprising a P-type AlGaAs back surface field, a P-type GaAs base region, an N-type AlGaAs emitting electrode, an N-type AlGaAs window layer, and an N⁺-type GaAs front-side contact layer that grow epitaxially in order on the P-type region of the tunnel junction, the front metal electrode layer is provided on the front-side contact layer.

13. The dual-junction thin film solar cell module as claimed in claim 3, wherein the GaAs cell comprising a P-type AlGaAs back surface field, a P-type GaAs base region, an N-type AlGaAs emitting electrode, an N-type AlGaAs window layer and an N⁺-type GaAs front-side contact layer that grow epitaxially in order on the P-type region of the tunnel junction, the front metal electrode layer is provided on the front-side contact layer.
